(19) United States
(12) Patent Application Publication
(10) Pub. No.: US 2002/0020851 A1
(43) Pub. Date: Feb. 21, 2002

(54) Heterobipolar transistor and a method of forming a SiGeC mixed crystal layer

(75) Inventor: Yoshiki Sakuma, Kawasaki (JP)

Correspondence Address: ARMSTRONG,WESTERMAN, HATTORI,, MCLELAND & NAUGHTON, LLP, 1725 K STREET, NW, SUITE 1000, WASHINGTON, DC, 20006, US

(73) Assignee: Fujitsu Limited, Kawasaki (JP)

(21) Appl. No.: 09/819,762

(22) Filed: Mar. 29, 2001

(30) Foreign Application Priority Data
Aug. 16, 2000 (JP) 2000-247057

(51) Int. Cl. H01L 21/331; H01L 21/8222; H01L 31/072; H01L 31/109

(52) U.S. Cl. 257/197; 438/312

(57) ABSTRACT

A heterobipolar transistor includes a base layer formed of a SiGeC ternary mixed crystal having a C concentration profile such that a C concentration in the base layer increases from a first interface facing an emitter layer to a second interface facing a collector layer. Further, the process of forming such a SiGeC ternary mixed crystal layer is disclosed.

### CROSS-REFERENCE TO RELATED APPLICATION

The present application is based on Japanese priority application No.2000-247057 filed on Aug. 16, 2000, the entire contents of which are hereby incorporated by reference.

### BACKGROUND OF THE INVENTION

The present invention generally relates to semiconductor devices and more particularly to a high-speed semiconductor device having a SiGeC ternary mixed crystal layer.

Today, Si bipolar transistors are regarded as being a classical semiconductor device.

Conventionally, Si bipolar transistors have been suffering from the problem of limited operational speed due to the limited carrier mobility in a Si crystal. Thus, optical telecommunication systems and radio telecommunication systems that are required to operate in the frequency band of GHz or more have used compound semiconductor devices that use a compound semiconductor material having characteristically a large electron mobility for the essential part thereof.

On the other hand, these compound semiconductor devices have a drawback in that it is difficult to form an integrated circuit on a Si substrate. Because of this drawback, it has been necessary to provide a high-frequency circuit of a compound semiconductor device separately to a signal processing circuits that are formed by a Si integrated circuit.

Meanwhile, it is known that there occurs an extensive formation of mixed crystal between Si and Ge, and there is a proposal to construct a high-speed semiconductor device that uses a binary mixed crystal of Si and Ge for the active part thereof. In a SiGe binary mixed crystal, it should be noted that there is induced a deformation in the crystal structure as a result of difference of atomic radius between Si and Ge, wherein the existence of such a deformation reduces the degree of symmetry of the crystal structure. As such a decrease of crystal symmetry imposes a limitation on the degree of freedom of electron scattering taking place therein, there arises a substantial increase of carrier mobility in such a SiGe mixed crystal as a result of reduced electron scattering caused by incorporation of Ge into a conventional Si crystal. A high-speed semiconductor device using such a SiGe binary mixed crystal is particularly suitable for integration on a common Si substrate together with other Si semiconductor devices.

In a SiGe binary mixed crystal, there occurs a decrease of bandgap as a result of substitution of Si with Ge in the crystal site of Si. Thus, by using such a SiGe mixed crystal doped to the p-type for the base layer of a Si bipolar transistor, it becomes possible to form a band discontinuity in the valence band at the interface between the base layer and the emitter layer, while such a band discontinuity in the valence band is useful for blocking the injection of minority carriers from the base layer into the emitter layer. Thus, a heterobipolar transistor using such a SiGe mixed crystal for the base layer thereof can improve the efficiency of carrier injection into the emitter similarly to conventional heterobipolar transistors, and can realize a high-speed response.

FIG. 1A shows the construction of a heterobipolar transistor using a SiGe binary mixed crystal according to a related art, while FIG. 1B shows the band structure of the heterobipolar transistor of FIG. 1A.

Referring to FIG. 1A, the heterobipolar transistor 10 is constructed on a Si substrate 11 formed with a device isolation trench 11A and an n⁺-type well 11B, wherein it can be seen that the n⁺-type well 11B carries thereon a collector layer 12 of n-type Si, and a thin base layer 13 of p-type SiGe binary mixed crystal formed on the collector layer 12.

The collector layer 12 and the baser layer 13 are patterned to form a mesa structure, and an emitter layer 14 of n⁺-type Si is formed on the base layer 13. Typically, the collector layer 12 and the emitter layer 14 are doped with P or As to the carrier density of 5×10¹⁷ cm⁻³ and 3×10²⁰ cm⁻³, respectively, and the base layer 13 is doped with B with a carrier density of about 5×10¹⁹ cm ⁻³. The emitter layer 14 carries thereon an emitter electrode 15, while the base layer 13 carries thereon a base electrode 16. Further, the n⁺-type well 11B carries thereon a collector electrode 17. Thus, the n⁺-type well 11B of FIG. 1A functions as a collector contact layer.

As represented in the band structure of FIG. 1B, the base layer 13 contains Ge with a concentration profile such that the Ge concentration increases from the interface between the base layer 13 and the emitter layer 14 to the interface between the base layer 13 and the collector layer 12, and there occurs a gradient in the conduction band Ec in the base layer 13 in such a manner that the conduction band Ec is inclined toward the collector layer 12. By providing such a graded compositional profile in the base layer 13, it becomes possible to accelerate the electrons causing a diffusion in the base layer 13 by applying thereto a drift electric field. Thereby, the operational speed of the heterobipolar 10 is improved. About the heterobipolar transistor using such a SiGe binary mixed crystal, reference should be made to the U.S. Pat. No. 5,353,912.

As the heterobipolar transistor of FIGS. 1A and 1B is formed by well-established technology used in the art of Si integrated circuit, the heterobipolar transistor is easily integrated into various integrated circuits including analog circuits, together with other information processing circuits.

In the heterobipolar transistor 10 of FIGS. 1A and 1B, however, there arises a problem, associated with the use of graded compositional profile of Ge in the base layer 13 with such a profile that the Ge concentration level increases toward the interface between the base layer 13 and the collector layer 12, in that a large lattice misfit appears at the part of the baser layer 13 facing the collector layer 12 in which the Ge concentration level the largest. Further, there is a risk that B (boron) used for doping the base layer 13 to the p-type easily diffuses into the adjacent collector layer 12 or the emitter layer 14 when a thermal annealing process is applied. Thus, the heterobipolar transistor 10 of the related art has an inherent problem in the stability against thermal annealing process.

Meanwhile, there is a proposal to suppress the diffusion of B from the base layer 13 to the adjacent collector layer 12 or the emitter layer 14 by incorporating a small amount of C into the base layer 13 of the SiGe binary mixed crystal (Lanzerotti, et al., Appl. Phys. Lett. 70(23), Jun. 9, 1997; Osten, H. J., et al., J. Vac. Sci. Technol. B16(3), May/June 1998, pp.1750-1753).

Further, there is a proposal to introduce C into the base layer of a SiGe mixed crystal in a Si or SiC heterobipolar transistor, as set forth in the U.S. Pat. No. 4,885,614 or in the Japanese Laid-Open Patent Publication 11-312686, such that the lattice misfit with respect to the Si substrate is relaxed and the degree of freedom for designing the heterobipolar transistor is increased particularly at the heterojunction interface between the base layer and the emitter layer.

However, such a conventional heterobipolar transistor has a drawback in that the concentration of C introduced into the base layer is very much limited, and thus, the occurrence of lattice misfit with respect to the Si substrate and associated problem of defect formation at such an interface could not be avoided effectively, particularly in the case a large Ge gradient is to be formed in the base layer. Thus, it has not been possible to obtain sufficient carrier acceleration in the base layer in such conventional heterobipolar transistors.

In order to introduce a large amount of C into the SiGeC mixed crystal, it is necessary to conduct the process such that the C atoms occupy a correct site of Si or Ge while avoiding formation of localized crystal strain and such that formation of deep impurity levels is avoided. This, however, has been difficult in conventional processes. Particularly, there is a report that introduction of high concentration C into a SiGe mixed crystal is difficult when the mixed crystal contains Ge with a high concentration level (J. P. Liu, et al., Appl. Phys. Lett. vol.76, pp.3546-3548, 2000).

In a conventional heterobipolar transistor that uses a SiGeC ternary mixed crystal for the base layer, there is another problem of notch formation in the conduction band in correspondence to the interface between the base layer and the collector layer or between the base layer and the emitter layer. When such a notch is formed in the conduction band, the notch functions as a potential barrier and the operational speed of the heterobipolar transistor is deteriorated.

### SUMMARY OF THE INVENTION

Accordingly, it is a general object of the present invention to provide a novel and useful heterobipolar transistor wherein the foregoing problems are eliminated.

Another and more specific object of the present invention is to provide a heterobipolar transistor having a base layer of a SiGeC ternary mixed crystal, wherein the degree of freedom of designing the heterobipolar transistor is improved and simultaneously the operational speed is maximized.

Another object of the present invention is to provide a heterobipolar transistor having a base layer of a SiGeC ternary mixed crystal wherein the acceleration of carriers achieved therein by drift is maximized.

Another object of the present invention is to provide a heterobipolar transistor having a base layer of a SiGeC ternary mixed crystal wherein a potential barrier formed at a heterojunction interface is minimized.

Another object of the present invention is to provide a heterobipolar transistor, comprising:

a substrate;

a collector layer formed on said substrate;

a base layer formed on said collector layer; and

an emitter layer formed on said base layer,

said base layer comprising a SiGeC ternary mixed crystal, with a C concentration profile such that a C concentration in said base layer increases from a first interface facing said emitter layer to a second interface facing said collector layer.

According to the present invention, it becomes possible to form a large concentration gradient of Ge and C in the base layer of the SiGeC mixed crystal, and it becomes possible to accelerate the carriers diffusing in the base layer as a result of the drift electric field induced by the compositional gradient. As a result, the transit time of the carriers through the base layer is reduced and the operational speed of the transistor is improved. Further, the present invention is effective for reducing the height of the spike appearing in the conduction band at the heteroepitaxial interface between the base layer and the emitter layer or between the base layer and the collector layer. As such a spike functions as a potential barrier, the reduction of the height of the spike results in an improvement of the operational speed of the heterobipolar transistor.

The heterobipolar transistor of the present invention can be formed on a Si substrate.

Another object of the present invention is to provide a heterobipolar transistor, comprising:

a substrate;

a collector layer formed on said substrate;

a base layer formed on said collector layer; and

an emitter layer formed on said base layer,

said base layer comprising a SiGe binary mixed crystal,

said emitter region including a first region contacting with said base layer, said collector layer including a second region contacting with said base layer,

at least one of said first and second regions containing C.

According to the present invention, the spike in the conduction band appearing at the heteroepitaxial interface between the base layer and the collector layer or between the base layer and the emitter layer is effectively suppressed by incorporating C in one or both of the first and second regions.

Another object of the present invention is to provide a method of forming a SiGeC mixed crystal layer, comprising the step of:

supplying SiH₄, GeH₄ and a gaseous source of C containing two or more C atoms in a molecule to a surface of a substrate respectively as sources of Si, Ge and C.

According to the present invention, it becomes possible to cause the C atoms to occupy a proper crystal site in the SiGeC mixed crystal layer, by setting the partial pressure of the SiH₄ source to a large value as compared with the source of C. By using a compound that contains two or more C atoms in a molecule for the source of C, it is possible to increase the C concentration in the SiGeC mixed crystal even in such a case the partial pressure of the C source is set low.

Other objects and further features of the present invention will become apparent from the following detailed description when read in conjunction with the attached drawings.

### BRIEF DESCRIPTION OF THE DRAWINGS

FIGS. 1A and 1B are diagrams showing the construction of a heterobipolar transistor according to a related art;

FIGS. 2A and 2B are diagrams showing the construction of a heterobipolar transistor according to a first embodiment of the present invention;

FIG. 3 is a diagram showing the construction of a deposition apparatus used in a second embodiment of the present invention;

FIGS. 4A-4C are diagrams showing the fabrication process of a heterobipolar transistor according to a third embodiment of the present invention;

FIG. 5 is a diagram showing the distribution profile of Si, Ge and C in a base layer of the heterobipolar transistor according to a fourth embodiment of the present invention;

FIG. 6 is a diagram showing the distribution profile of Si, Ge and C in a base layer of the heterobipolar transistor according to a fifth embodiment of the present invention;

FIGS. 7A and 7B are diagrams showing the band structure of a heterobipolar transistor according to a sixth embodiment of the present invention; and

FIG. 8 is a diagram showing the band structure of a heterobipolar transistor according to a seventh embodiment of the present invention.

### DETAILED DESCRIPTION OF THE INVENTION

[First Embodiment]

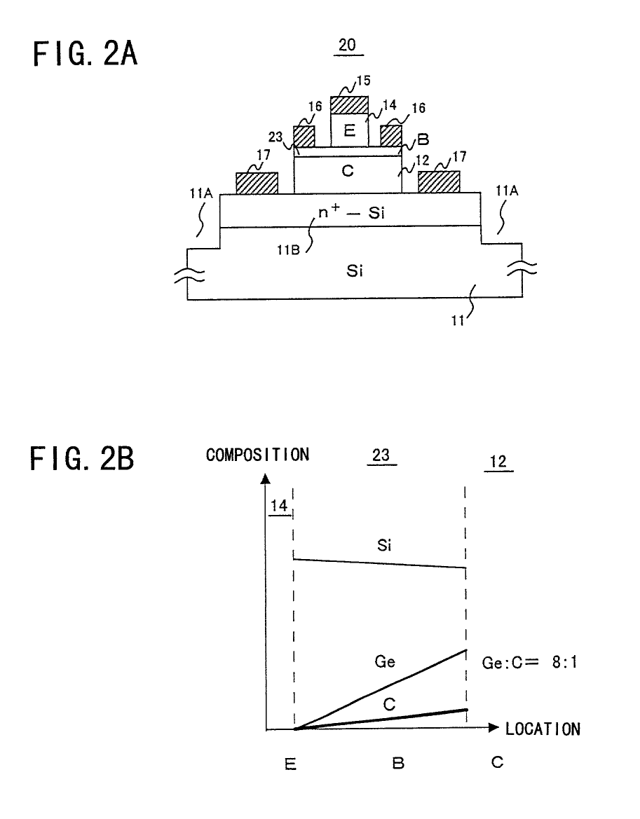

FIGS. 2A and 2B show the construction of a heterobipolar transistor 20 according to a first embodiment of the present invention, wherein those parts corresponding to the parts described previously are designated by the same reference numerals and the description thereof will be omitted.

Referring to FIG. 2A, the heterobipolar transistor 20 has a construction similar to that of the heterobipolar transistor 10 except that the base layer 13 is replaced by a SiGeC ternary mixed crystal having a compositional gradient as represented in FIG. 2B. The base layer 23 may have a thickness of 50 nm and is doped with B to a carrier density of 8×10¹⁹ cm⁻³.

Referring to FIG. 2B, the base layer 23 contains substantially no Ge and C at the interface to the emitter layer 14, while the Ge concentration and the C concentration increase together in the base layer 23 toward the interface to the collector layer 12 continuously and uniformly. Thus, at the interface between the collector layer 12 and the base layer 23, the mixed crystal, represented as Si_{1-x-y}GeₓC_{y}, has a composition characterized by the compositional parameters x and y of 0.25 and 0.03, respectively.

As represented in FIG. 2B, the ratio between the compositional parameter x for Ge and the compositional parameter y for C is maintained more or less constant in the base layer 23, and the concentration of Ge and C becomes maximum at the interface between the base layer 23 and the collector layer 12. In the example of FIG. 2B, the compositional parameter x is set to be about eight times the compositional parameter y (Ge:C=8:1). When the compositional parameters x and y are chosen as such, the base layer 23 achieves a lattice matching with respect to the Si substrate over the entire thickness thereof.

When such a base layer 23 is used in the heterobipolar transistor 20, the diffusion of B from the base layer 23 into the adjacent collector layer 12 is suppressed effectively due to the presence of C in the base layer 23, and a transistor having a stabilized characteristic is obtained. In view of the fact that the C concentration is changed together with the Ge concentration in the SiGeC ternary mixed crystal, the lattice strain in the base layer 23 is effectively suppressed and no defects are introduced by the lattice misfit even when the Ge concentration is changed over a wide compositional range. Thus, it becomes possible to realize a large compositional gradient of Ge in the base layer 23 for enhanced carrier acceleration. Thus, the heterobipolar transistor 20 of the present invention can achieve a high-speed operation exceeding the heterobipolar transistor 10 of the related art.

By controlling the Ge concentration with respect to the C concentration, it is possible in the heterobipolar transistor 20 of the present embodiment, to optimize the strain in the base layer 23, while such an optimization contributes to the optimization of carrier mobility in the base layer 23.

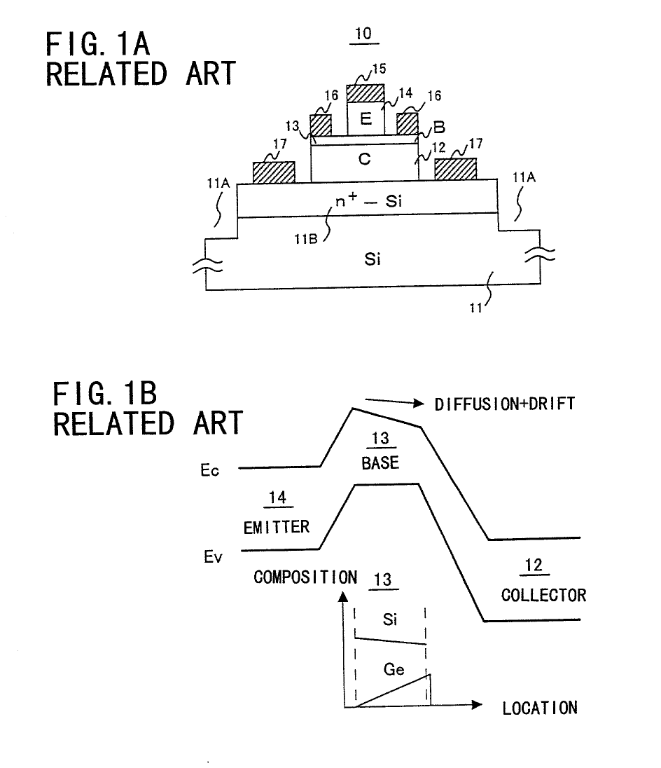

In such a mixed crystal system of SiGeC, it is discovered recently by a theoretical calculation that the bandgap decreases with the C concentration (Ohfuti, M., et al., Phys. Rev. B vol.60, pp.15515-15518, 1999). This means that the gradient of the conduction band explained with reference to FIG. 1B is enhanced further in the base layer 23, while such a increase of the gradient facilitates the carrier acceleration further.

[Second Embodiment]

Next, the method of forming a SiGeC ternary mixed crystal layer constituting the base layer 23 of FIGS. 2A and 2B will be explained as a second embodiment of the present invention.

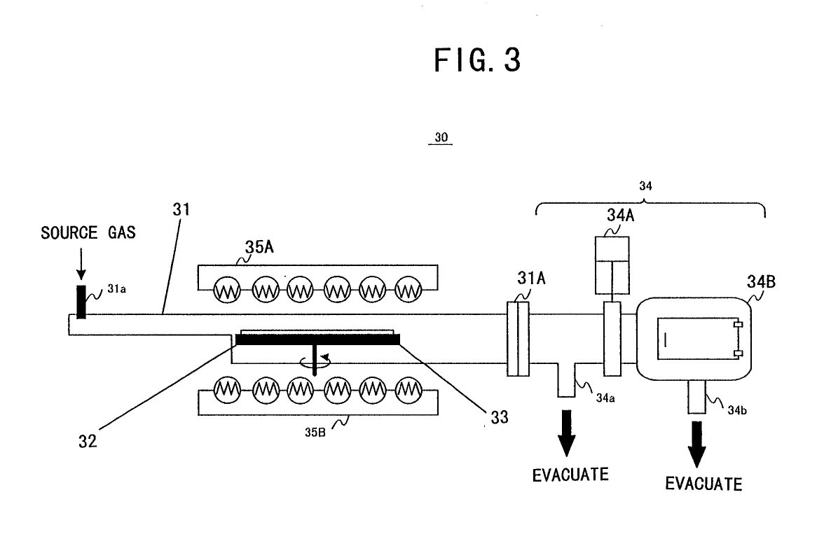

FIG. 3 shows the construction of a vapor-phase deposition apparatus 30 used for forming the SiGeC mixed crystal in the present embodiment.

Referring to FIG. 3, the vapor-phase deposition apparatus 30 includes a quartz glass reactor 31 accommodating therein a rotatable graphite susceptor 32, wherein the graphite susceptor 32 is adapted to hold a substrate 31 such as a Si wafer to be processed. In the illustrated example, the graphite susceptor 32 is covered by an SiC coating not illustrated.

The quartz reactor 31 is connected with a wafer loading/unloading unit 34 including a gate valve 34A and a load-lock chamber 34B via a flange 31A, and the quartz reactor 31 is evacuated through an evacuation port 34a provided on the loading/unloading unit 34. Further, the load-lock chamber 34B itself is evacuated via another evacuation port 34b. Further, a gaseous source is introduced into quartz glass reactor 31 via an inlet port 31a. Adjacent to the reactor 31, there are provided lamp heating units 35A and 35B for heating the substrate 33 on the susceptor 32.

Next, the process of forming a SiGeC ternary mixed crystal layer on a Si substrate conducted in the apparatus 30 will be described.

First, a (100)-oriented Si substrate 33 is introduced into the reactor 31 after a cleaning process, by transporting the substrate 33 through the load-lock chamber 34B and the gate valve 34A, and a baking process is conducted at 950° C. while flowing an H₂ carrier gas for removal of surface oxide film.

Next, the substrate temperature is lowered to a temperature of 550-650° C. and source gases of SiH₄, GeH₄ and (CH₃)₂SiH₂ (dimethylsilane) or (CH₃)₃SiH (trimethylsilane) are introduced into the reactor 31 via the inlet port 31a respectively as the source of Si, the source of Ge and the source of C. Further, the pressure inside the reactor 31 is set to about 1.3 kPa (10 Torr) and deposition of a SiGeC mixed crystal layer of conducted on the substrate 33.

It should be noted that there have already been the art of forming a SiGeC mixed crystal layer by a CVD process. However, it has been difficult to introduce a large amount of C atoms into the proper crystal site, such that the introduced C atoms substitute Si or Ge atoms in the crystal structure of the SiGe mixed crystal. It is known that a large partial pressure is needed for the SiH₄ gas, used for the source of Si, in order to settle the C atoms into the proper crystal site (Mi, J. et al., J. Vac. Sci. Tech. B14(3), pp.1660-1669, 1996), while such an increase of the SiH₄ partial pressure contradicts with the requirement of increasing the partial pressure of the C source in the reactor 31. Thus, when the partial pressure of the C source is increased for increasing the C concentration in the mixed crystal, there occurs an inevitable decrease of the SiH4 partial pressure and the C atoms occupy an unwanted site such as an interstitial site. When the C atoms have entered into such an unwanted crystal site, there is induced a local strain or deep impurity level in the crystal structure. Further, such C atoms tend to work as a source of dislocations or various defects.

Contrary to the conventional art, the present invention uses a compound that contains two or more C atoms in a molecule such as (CH₃)₂SiH₃ or (CH₃)₃SiH in place of conventionally used compound CH₃SiH₃ (monomethylsilane). As the C source used in the present invention contains two or more C atoms in the molecule, it is possible to increase the concentration of C in the mixed crystal without causing unwanted decrease of the SiH4 partial pressure. According to the present invention, it is possible to introduce C into the substituting site of Si or Ge with a concentration of 5-6 atomic percent.

Conventionally, it has been known that the incorporation of C into the SiGeC mixed crystal, particularly the proportion of the C atoms substituting the Si or Ge atoms, decreases with increasing Ge concentration in the mixed crystal (Liu, J. P., Appl. Phys. Lett. vol.76, p.3546-3548, 2000, op cit). Thus, it has been difficult to introduce a large amount of C atoms into a SiGeC mixed crystal has been difficult, particularly in the case the mixed crystal contains a large amount of Ge.

In the present invention, this problem is successfully avoided by the process that includes the steps of first supplying the SiH₄ gas into the reactor 31 of the deposition apparatus 30 of FIG. 3 and covering the surface of the Si substrate with Si atoms, followed by supplying the (CH₃)₂SiH₂ or (CH₃)₃SiH gas so as to introduce C atoms into proper crystal sites, and by supplying the GeH₄ gas thereafter. According to such a process, it becomes possible to introduce the C atoms with high concentration even in the case the SiGeC mixed crystal contains Ge with high concentration. Thus, by repeating the foregoing steps, it becomes possible to form a SiGeC mixed crystal containing Ge and C with high concentrations. In such a process, it is possible to control the compositional profile of the SiGeC mixed crystal as desired by controlling the number of the supplying steps of the SiH₄ gas, the GeH₄ gas and the C source gas.

[Third Embodiment]

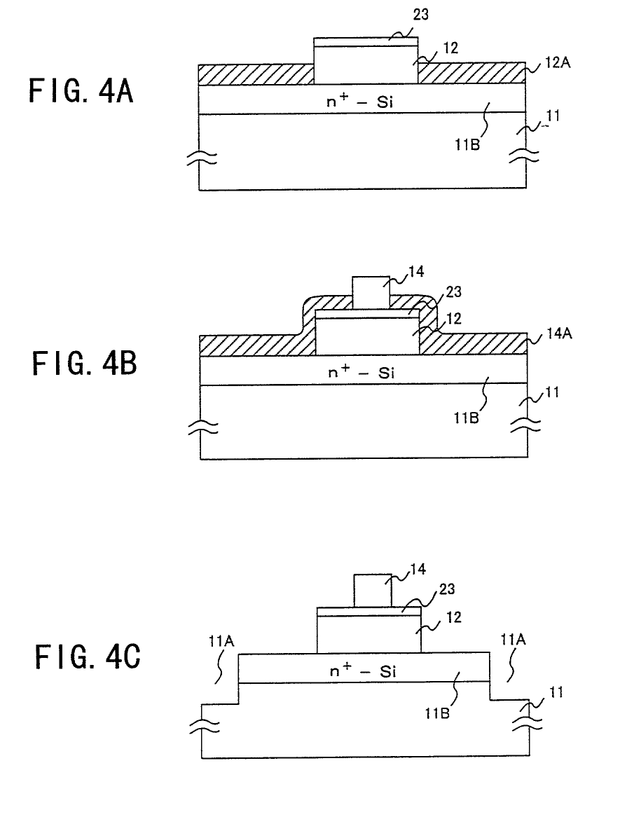

Next, the fabrication process of the heterobipolar transistor 20 of FIGS. 2A and 2B conducted in the deposition apparatus 30 of FIG. 3 will be described with reference to FIGS. 4A-4C.

Referring to FIG. 4A, an insulating mask pattern 12A is formed on the surface of the Si substrate 11 formed already with the n+-type well 11B, such that the mask pattern 12A has an opening exposing the part where the collector layer 12 is to be formed.

Next, a Si layer and a SiGeC mixed crystal layer are deposited consecutively in the reactor 31 of the deposition apparatus 30 to form the collector layer 12 and the base layer 23. Thereby, it should be noted that the collector layer 12 is formed at the substrate temperature of 600-750° C. while using the source gas of SiH₄ and further a doping gas of PH₃ or AsH₃, wherein the source gas and the doping gas are introduced into the reactor 31 together with an H₂ carrier gas. On the other hand, the formation of the base layer 23 is conducted by supplying SiH₄, GeH₄ and one of (CH₃)₂SiH₂ or (CH₃)₃SiH as the source gases of Si, Ge and C similarly to the previous embodiment, wherein a doping gas of p-type impurity such as B2H6 is added to the source gases. As explained previously, it is possible to settle the C atoms in the proper or nominal crystal site of the SiGeC mixed crystal, by switching the supply of the SiH₄ gas, the (CH₃)₂SiH₂ or (CH₃)₃SiH gas, and the GeH₄ gas. Thereby, a SiGeC mixed crystal containing C atoms with high concentration can be formed with an arbitrary compositional profile.

Next, in the step of FIG. 4B, the insulating mask 12A is removed and another insulating mask 14A is provided such that the insulating mask 14A exposes the part of the base layer on which the emitter layer 14 is to be formed. Further, the emitter layer 14 is formed on the base layer 23 while using the insulating mask 14A as a deposition mask by supplying SiH₄ and PH₃ or AsH₃.

Next, in the step of FIG. 4C, the insulating mask 14A is removed and the device-isolation trench 11A is formed by a resist process. Further, the collector electrode 17, the base electrode 16 and the emitter electrode 15 are formed by a lift-off process, and the heterobipolar transistor of FIG. 2A is completed.

[Fourth Embodiment]

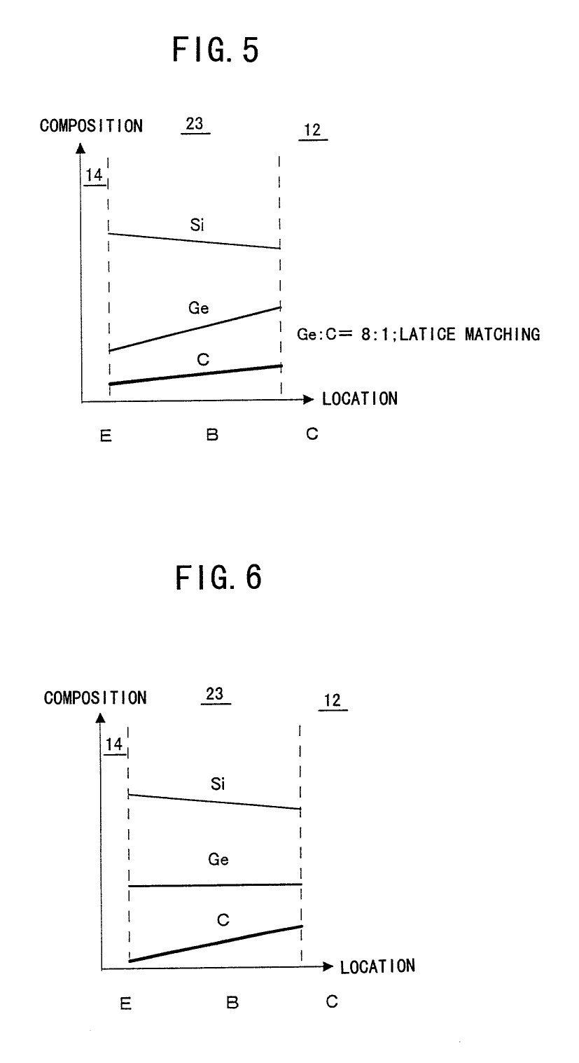

FIG. 5 shows the compositional profile formed in the SiGeC mixed crystal base layer 23 of the heterobipolar transistor 20 according to a fourth embodiment of the present invention.

Referring to FIG. 5, it is noted that the base layer 23 of the present embodiment has non-zero concentration for Ge and C at the interface between the base layer 23 and the emitter layer 14. Thus, the interface between the base layer 23 and the emitter layer 14 forms a heteroepitaxial interface in the present embodiment.

In such a construction, it is noted that the profile of the Ge and C in the base layer 23 becomes gentler than in the case of the compositional profile of FIG. 2B. Further, the ratio between the compositional parameter x and the compositional parameter y is not constant, and thus, there occurs an accumulation of strain in the base layer 23 in the present embodiment. In the illustrated example, a lattice matching is achieved at the interface between the base layer 23 and the collector layer 12, and thus, the base layer 23, while accumulating a strain therein to some extent, does not experience such a strain that induces formation of defects such as dislocations. In the base layer 23 of the present embodiment, it is possible to increase the carrier mobility in the base layer 23 by optimizing the strain therein.

[Fifth Embodiment]

FIG. 6 shows a compositional profile of the SiGeC mixed crystal base layer 23 of the heterobipolar transistor 20 according to a fifth embodiment of the present invention.

Referring to FIG. 6, the Ge concentration in the base layer 23 is generally constant and only the C concentration changes such that the C concentration increases from the interface to the emitter layer 14 to the interface to the collector layer 12.

Even in such a case in which only the C concentration changes in the base layer 23, there appears a gradient in the conduction band in correspondence to the compositional gradient of C, and the electrons traveling through the base layer 23 experience acceleration by a drift electric field. As explained before, there can be a situation in which introduction of C with high concentration level into a SiGeC mixed crystal is difficult. In the example of FIG. 6, it becomes possible to introduce a large amount of C in the base layer 23 by maintaining a low Ge concentration therein.

[Sixth Embodiment]

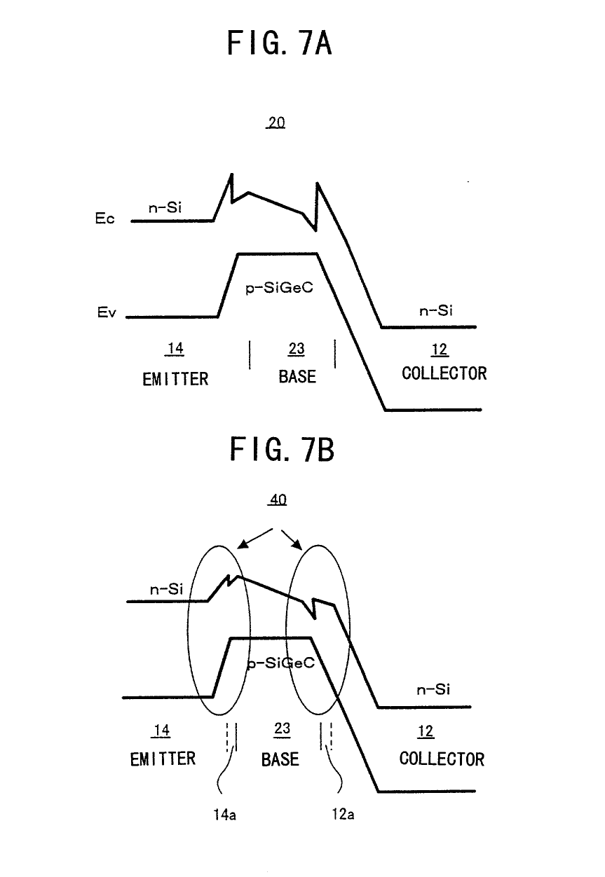

FIG. 7A shows the band structure of the heterobipolar transistor 20 according to the embodiment of FIG. 5.

Referring to FIG. 7A, it can be seen that the heterobipolar transistor 20 has two heteroepitaxial interfaces, one at the interface between the base layer 23 and the collector layer 12 and the other between the base layer 23 and the emitter layer 14. Associated with the heteroepitaxial interface, there appears a predominant spike in the conduction band in each of these heteroepitaxial interfaces. As such a spike in the conduction band functions as a potential barrier to the electrons transiting the base layer 23 along the conduction band Ec thereof, the heterobipolar transistor suffers from the problem of decrease of operational speed.

FIG. 7B, on the other hand, shows the band structure of a heterobipolar transistor 40 according to a sixth embodiment of the present invention that remedies the foregoing problem.

In the present embodiment, C atoms are introduced into one or both of the emitter layer 14 and the collector layer 12 in correspondence to a region 14a of the emitter layer 14 in which the emitter layer 14 makes a contact with the base layer 23 or in correspondence to a region 12a of the collector layer 12 in which the collector layer 12 makes a contact with the base layer 23. As a result an SiC layer is formed in correspondence to the foregoing regions 12a and 14a in the heterobipolar transistor 40 of the present embodiment.

By forming an SiC layer, the conduction band Ec shifts in the lower energy side in correspondence to the regions 12a and 14a, and the spike formed in the conduction band Ec disappears substantially. As a result, injection of electrons from the emitter layer 14 into the base layer 23 or the injection of electrons from the base layer 23 into the collector layer 12 occurs efficiently, and the base current caused by the electrons blocked at the base/collector interface is reduced substantially. Thereby, the bipolar transistor 40 of the present embodiment shows an excellent electric performance.

It should be noted that the introduction of C atoms into the interface regions 14a or 12a can be achieved easily by using the deposition apparatus of FIG. 3.

[Seventh Embodiment]

It should be noted that the construction of FIG. 7B can be applied to the heterobipolar transistor 10 of FIGS. 1A and 1B that uses the base layer formed of a SiGe binary mixed crystal.

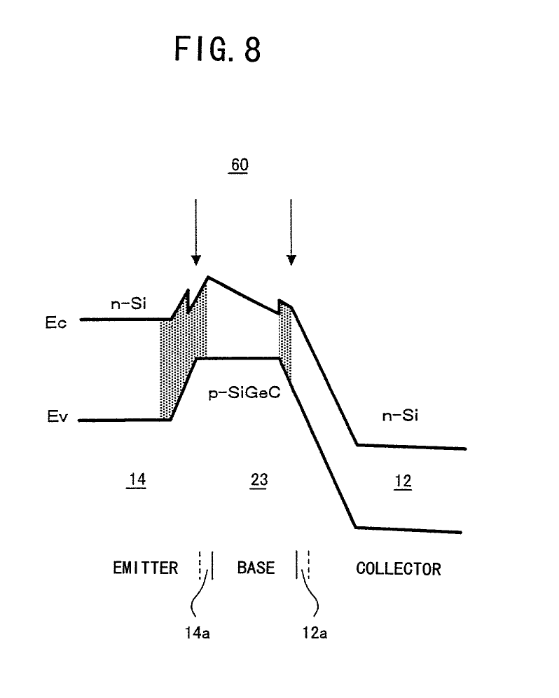

FIG. 8 shows the construction of a heterobipolar transistor 60 according to a seventh embodiment of the present invention in which the spike formed in the conduction band at the emitter/base interface or at the emitter/collector interface in the heterobipolar transistor 10 of FIGS. 1A and 1B is eliminated. In FIG. 8, those parts corresponding to the parts described previously are designated by the same reference numerals and the description thereof will be omitted.

Referring to FIG. 8, it can be seen that the heterobipolar transistor 60 includes the interface region 14a in the emitter layer 14 in which C atoms are introduced. Thus, the interface region 14a has a composition represented by SiC. Further, the heterobipolar transistor 60 includes the interface region 12a in the collector layer 12 in which C atoms are introduced. Thus, the interface region 12a has a composition represented as SiC. As a result of formation of the SiC regions 12a and 14a respectively at the interface between the base layer 23 and the collector layer 12 and at the interface between the base layer 23 and the emitter layer 14, the spike at such heteroepitaxial interfaces disappears substantially and the characteristic of the heterobipolar transistor 60 is improved.

In the embodiment of FIG. 8, it should be noted that such an introduction of C atoms may be conducted into the part of the base layer 13 adjacent to the foregoing interface region 12a or 14a. Such an introduction of the C atoms can be achieved easily by using the deposition apparatus 30 of FIG. 3.

Further the present invention is not limited to the embodiments described heretofore, but various variations and modifications may be made without departing from the scope of the invention.

What is claimed is:

1. A heterobipolar transistor, comprising:
a substrate;
a collector layer formed on said substrate;
a base layer formed on said collector layer; and
an emitter layer formed on said base layer,
said base layer comprising a SiGeC ternary mixed crystal having a C concentration profile such that a C concentration in said base layer increases from a first interface facing said emitter layer to a second interface facing said collector layer.

2. A heterobipolar transistor as claimed in claim 1, wherein said substrate is a Si substrate.

3. A heterobipolar transistor as claimed in claim 1, wherein said base layer has a Ge concentration substantially constant from said first interface to said second interface.

4. A heterobipolar transistor as claimed in claim 1, wherein said base layer has a Ge concentration that increases from said first interface to said second interface.

5. A heterobipolar transistor as claimed in claim 4, wherein said base layer has a C concentration and a Ge concentration that change from said first interface to said second interface while maintaining a constant ratio.

6. A heterobipolar transistor as claimed in claim 5, wherein said ratio is set so as to avoid defect formation in said base layer due to lattice misfit with respect to said substrate, from said first interface to said second interface.

7. A heterobipolar transistor as claimed in claim 5, wherein said ratio is set so as to achieve a lattice matching in said base layer with respect to said substrate, from said first interface to said second interface.

8. A heterobipolar transistor as claimed in claim 4, wherein said Ge concentration and said C concentration change from said first interface to said second interface continuously.

9. A heterobipolar transistor as claimed in claim 1, wherein at least one of a Ge concentration and said C concentration has a non-zero value at said first interface.

10. A heterobipolar transistor as claimed in claim 1, wherein at least one of a first region of said emitter layer adjacent to said base layer and a second region of said collector layer adjacent to said base layer contains C.

11. A heterobipolar transistor as claimed in claim 10, wherein both of said first and second regions contain C.

12. A heterobipolar transistor, comprising:
a substrate;
a collector layer formed on said substrate;
a base layer formed on said collector layer; and
an emitter layer formed on said base layer,
said base layer comprising a SiGe binary mixed crystal,
said emitter region including a first region contacting with said base layer, said collector layer including a second region contacting with said base layer,
at least one of said first and second regions containing C.

13. A heterobipolar transistor as claimed in claim 12, wherein both of said first and second regions contain C.

14. A method of forming a SiGeC mixed crystal layer, comprising the step of:
supplying SiH₄, GeH₄ and a gaseous source of C containing two or more C atoms in a molecule to a surface of a substrate respectively as sources of Si, Ge and C.

15. A method as claimed in claim 14 wherein said substrate is a Si substrate.

16. A method as claimed in claim 14, wherein one of (CH₃)₂SiH₂ and (CH₃)₃SiH is used as said gaseous source of C.

17. A method as claimed in claim 14, wherein said step of supplying SiH₄, GeH₄ and said gaseous source of C comprises the steps of: (a) supplying SiH₄ to said substrate surface; (b) supplying, after said step (a), said gaseous source of C to said substrate surface; and (c) supplying, after said step (b), GeH4 to said substrate surface.

18. A method as claimed in claim 14, wherein said gaseous source of C is supplied with a variable rate with a growth of said SiGeC mixed crystal layer.
